(19) United States
(12) Patent Application Publication
(10) Pub. No.: US 2012/0313863 A1
(43) Pub. Date: Dec. 13, 2012

(54) INTEGRATED TOUCH PANEL STRUCTURE AND MANUFACTURING METHOD THEREOF

(75) Inventor: Fu-Tseng Hsu, Taoyuan (TW)

(73) Assignee: Hannstar Display Corporation, New Taipei City (TW)

(21) Appl. No.: 13/253,951

(22) Filed: Oct. 5, 2011

(30) Foreign Application Priority Data
Jun. 7, 2011 (TW) 100119860

(51) Int. Cl. G06F 3/041; H05K 13/00

(52) U.S. Cl. 345/173; 29/592.1

(57) ABSTRACT

An integrated touch panel structure and manufacturing method thereof are described. The integrated touch panel structure is integrated by a first sensing layer, a displaying layer, a backlight plate and a composite component layer. The composite component layer includes a second sensing layer and a processing circuit layer. The processing circuit layer further includes a metal area for preventing a touch signal from electromagnetic interference to increase the precision of the touch signal.

### FIELD OF THE INVENTION

The present invention relates to a touch panel structure and method thereof, and more particularly to an integrated touch panel structure and manufacturing method thereof for integrating a first sensing layer, a displaying layer, a backlight plate and a composite component layer wherein the composite component layer has a second sensing layer and a processing circuit layer.

### BACKGROUND OF THE INVENTION

With the rapid development of information technology, many electronic products widely currently utilizes touch technology as a manner of message input and the user can read or browse the information on the display panel or transmit the input message when the user touches the display panel by finger or stylus pen, which replace the manner of keypad or keyboard installed in the conventional electronic products. For example, touch panel has been a rush-developing market for several manufacturers due to the incitation of IPhone's great demand in the cell phone market.

Conventionally, the touch panel includes a liquid crystal display (LCD) module, a capacitive touch panel, a switch plate, an electromagnetic touch board and an electromagnetic touch antenna board. The LCD module displays a program execution window and the capacitive touch panel generates a capacitive touch signal. The electromagnetic touch antenna board forms the electromagnetic touch signal and the electromagnetic touch board processes the electromagnetic touch signal. The switch plate switches to select either the capacitive touch signal or the electromagnetic touch signal. Since the switch plate, the electromagnetic touch board and the electromagnetic touch antenna board are independently disposed, i.e. the switch plate, the electromagnetic touch board and the electromagnetic touch antenna board are different circuit boards, such manner will induce the enlarged noise and is subject to electromagnetic interference (EMI), which results in difficult adjustment of touch signal. Further, the switch plate, the electromagnetic touch board and the electromagnetic touch antenna board are connected by connectors and cables using soldering technique, which disadvantageously increases the resistance between the connectors and cables. Consequently, there is a need to develop a novel touch panel structure to solve the aforementioned problems.

### SUMMARY OF THE INVENTION

The first objective of the present invention is to provide an integrated touch panel structure and manufacturing method thereof by integrating a plurality of circuit components into a composite component layer with bigger area to properly arrange the positions of the circuit components for effectively separating the circuit components from the elements with noise interference.

The second objective of the present invention is to provide an integrated touch panel structure and manufacturing method thereof by employing the spare area of the composite component layer as the electromagnetic shielding area to reduce the electromagnetic interference of the sensing signals for increasing the calculation accuracy of the sensing signals.

The third objective of the present invention is to provide an integrated touch panel structure and manufacturing method thereof by employing the composite component layer to shrink the transmission lines among the circuit components for reducing the resistance of the transmission lines.

The fourth objective of the present invention is to provide an integrated touch panel structure and manufacturing method thereof by employing the composite component layer for enlarging the heat dissipation area of the circuit components and for improving the mechanical assembly strength of the integrated touch panel structure.

According to the above objectives, the present invention sets forth the integrated touch panel structure in one embodiment. The integrated touch panel structure includes a first sensing layer, a displaying layer, a backlight plate and a composite component layer. The displaying layer displays a program execution window wherein the first sensing layer is disposed on a first side-wall of the displaying layer and generates a first sensing signal. The first sensing layer generates the first sensing signal corresponding to a touch operation when the touch operation is performed on the program execution window. The backlight plate disposed on a second side-wall opposite to the first side-wall of the displaying layer generates a backlight to illuminate the displaying layer.

The composite component layer is disposed on the backlight plate and opposite to the displaying layer. The composite component layer includes a second sensing layer and a processing circuit layer. The second sensing layer contacts the backlight plate and generates a second sensing signal corresponding to an inductive operation when the inductive operation is performed on the program execution window. The processing circuit layer is formed on the second sensing layer and has a first touch module corresponding to the first sensing layer, a second touch module corresponding to the second sensing layer and a switch unit. The first touch module converts the first sensing signal into a first coordinate value corresponding to a touch operation. The second touch module converts the second sensing signal into a second coordinate value corresponding to an inductive operation. The switch unit switches the first touch module and the second touch module for selecting either the first coordinate value or the first coordinate value. An area of the processing circuit layer is either greater than or equal to an area of the second sensing layer. At least one metal area is further formed on a spare area of the processing circuit layer except for the area of the first touch module, the second touch module and the switch unit.

In another embodiment, the present invention sets forth the manufacturing method of the integrated touch panel structure. The method of manufacturing the integrated touch panel structure includes the following steps.

(1) A displaying layer is provided for displaying a program execution window thereon.

(2) A backlight plate is formed on a first side-wall of the displaying layer.

(3) A composite component layer is formed on the backlight plate for electrically connecting the composite component layer to the backlight plate, wherein the composite component layer is opposite to the displaying layer based on the backlight plate. The composite component layer is a multi-layer printed circuit board. During the step (3) of forming the composite of component layer, it further includes the following steps. In step (3-1), a second sensing layer is formed for contacting the backlight plate and generating a second sensing signal by the second sensing layer. In step (3-2), a circuit layout layer and the processing circuit layer are formed on the second sensing layer wherein the processing circuit layer has a first touch module, a second touch module and a switch unit, and an area of the processing circuit layer is either greater than or equal to an area of the second sensing layer. In step (3-3), at least one metal area is formed on a spare area of the processing circuit layer except for the area of the first touch module, the second touch module and the switch unit. That is, the processing circuit layer has a metal area except for the area of the first touch module, the second touch module and the switch unit. Further, during the step (3-2) of forming the processing circuit layer on the second sensing layer, it further includes the following steps. In step (3-21), a timing controller is formed for generating a timing controlling signal and a data signal. In step (3-22), a backlight driving module is formed for driving the backlight plate according to the timing controlling signal. In step (3-23), a power module is formed for providing the integrated touch panel structure with power for operation, wherein the first touch module, the second touch module and the switch unit are distant from the timing controller, the backlight driving module and the power module respectively at a predetermined distance (PD).

(4) A first sensing layer is formed on a second side-wall of the displaying layer opposite to the first side-wall to generate the first sensing signal by the first sensing layer. The first sensing layer is a capacitive type touch board and electrically connected to the composite component layer.

The present invention provides an integrated touch panel structure and manufacturing method thereof by integrating a plurality of circuit components into a composite component layer with bigger area to properly arrange the positions of the circuit components for effectively separating the circuit components from the elements with noise interference. Further, the spare area of the composite component layer is employed as the electromagnetic shielding area to reduce the electromagnetic interference of the sensing signals for increasing the calculation accuracy of the sensing signals. Additionally, the composite component layer is employed to shrink the transmission lines among the circuit components for reducing the resistance of the transmission lines. Moreover, the composite component layer is employed for enlarging the heat dissipation area of the circuit components and for improving the mechanical assembly strength of the integrated touch panel structure.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic top view of an integrated touch panel structure according to one embodiment of the present invention;

FIG. 2 is a schematic side view of the integrated touch panel structure according to one embodiment of the present invention;

FIG. 3 is a flow chart of a manufacturing method of the integrated touch panel structure according to one embodiment of the present invention;

FIG. 4 is a flow chart of forming a composite component layer according to one embodiment of the present invention; and

FIG. 5 is a flow chart of forming a processing circuit layer on the second sensing layer according to one embodiment of the present invention.

### DETAILED DESCRIPTION OF THE PREFERRED EMBODIMENTS

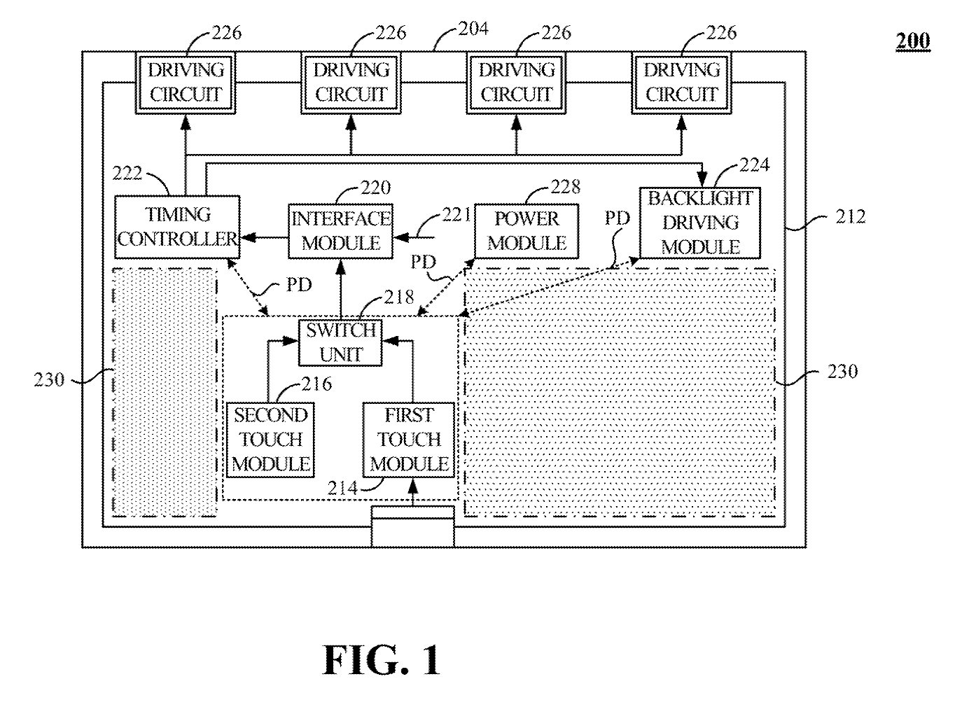

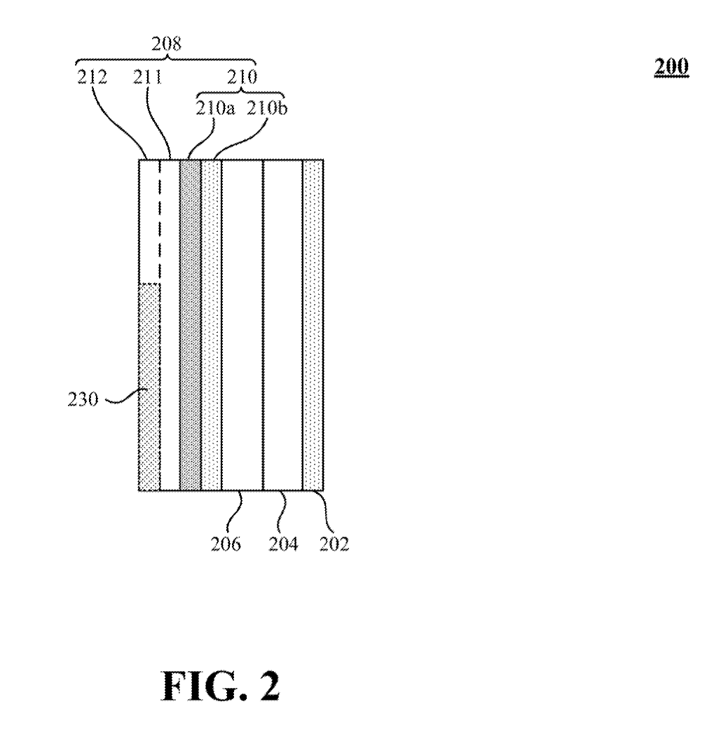

Please refer to FIG. 1 and FIG. 2. FIG. 1 is a schematic top view of an integrated touch panel structure 200 according to one embodiment of the present invention. FIG. 2 is a schematic side view of the integrated touch panel structure 200 according to one embodiment of the present invention. The integrated touch panel structure 200 includes a first sensing layer 202, a displaying layer 204, a backlight plate 206 and a composite component layer 208. The first sensing layer 202 generates a first sensing signal for sensing the touch operation of user's finger on the first sensing layer 202. In one case, the first sensing layer 202 is a capacitive type touch board. For example, the capacitive type touch board is an indium tin oxide (ITO) layer. The displaying layer 204 displays a program execution window wherein the first sensing layer 202 is disposed on a first side-wall of the displaying layer 204. The first sensing layer 202 generates the first sensing signal corresponding to a touch operation when the touch operation is performed on the program execution window. In other words, when the user touches the first sensing layer 202 corresponding to the program execution window, the first sensing signal is generated, wherein the application program (AP) selected by the user on the program execution window is performed. The backlight plate 206 is disposed on a second side-wall opposite to the first side-wall of the displaying layer 204 for generating a backlight to illuminate the displaying layer 204. For example, the backlight plate 206 is a light source composed of light emitted diodes (LEDs) or light components. The composite component layer 208 is disposed on the backlight plate 206 and opposite to the displaying layer 204. That is, the composite component layer 208 and the displaying layer 204 are positioned in different side-wall of the backlight plate 206. In one embodiment, the composite component layer 208 is a multi-layer printed circuit board (PCB). The detailed structure of the composite component layer 208 is described as follows.

The composite component layer 208 further includes a second sensing layer 210, a circuit layout layer 211 and a processing circuit layer 212. The second sensing layer 210 contacts the backlight plate 206 and generates a second sensing signal corresponding to an inductive operation when the inductive operation is performed on the program execution window. For example, when the user utilizes an electromagnetic type stylus to induct the second sensing layer 210 corresponding to the program execution window, the second sensing signal is generated and it represents that the application program (AP) selected by the user on the program execution window is performed. The first sensing layer 210 is an electromagnetic type touch board. In one embodiment, the second sensing layer 210 further includes a first axial layer 210a and a second axial layer 210b. The second axial layer 210b is disposed on the first axial layer 210a and interlaced with the first axial layer 210a to form the second sensing layer 210. The first axial layer 210a senses a directional signal of the second sensing signal along an coordinate X and the second axial layer 210b senses a directional of the second sensing signal along an coordinate Y perpendicular to the coordinate X so that the directional signals along the coordinates X and Y constructs the second sensing signal. Specifically, the second sensing layer 210 is integrated into the composite component layer 208 to replace the conventional antenna board to effectively decrease the total thickness of the integrated touch panel structure 200.

In the composite component layer 208, the processing circuit layer 212 is formed on, e.g. adhered to or attached to, the second sensing layer 210 and has a first touch module 214 corresponding to the first sensing layer 202, a second touch module 216 corresponding to the second sensing layer 210, a switch unit 218, an interface module 220, a timing controller 222, a backlight driving module 224, a driving circuit 226 and a power module 228. The first sensing layer 202 is electrically connected to the first touch module 214 and the second sensing layer 210 is electrically connected to the second touch module 216. The first touch module 214 and the second touch module 216 are connected to the switch unit 218, respectively. The switch unit 218 is connected to the interface module 220 and the timing controller 222 connects the interface module 220 to the driving circuit 226. The timing controller 222 further connects the interface module 220 to the backlight driving module 224 and the backlight driving module 224 is coupled to the backlight plate 206.

In one embodiment, the second sensing layer 210 is connected to the second touch module 216 via the through holes (not shown) of the composite component layer 208 to replace the external cable and the connector disposed on the composite component layer 208. That is, the second sensing layer 210 directly connects to the pins of the second touch module 216 via the through holes of the processing circuit layer 212. Moreover, the second touch module 216 utilizes the transmission lines of the composite component layer 208 to be connected to the switch unit 218 to replace the external cable and connector disposed on the composite component layer 208 for connecting the second touch module 216 to the switch unit 218. In other words, the second touch module 216 directly connects the pins of the switch unit 218 via the transmission line of the processing circuit layer 212. Based on the above descriptions, the second touch module 216 is electrically connected to the second sensing layer 210 and the switch unit 218 respectively via the through holes and transmission lines to improve the conventional external cable and connector.

In the processing circuit layer 212, the first touch module 214 calculates the first sensing signal of the first sensing layer 202 to generate the first coordinate value corresponding to the position of the touch operation. For example, the capacitance change between the ITO layer and the user body is detected to calculate the first coordinate value according to the induced current from the touched position. The second touch module 216 calculates the second sensing signal of the second sensing layer 210 to generate the second coordinate value corresponding to the position of the inductive operation. Specifically, the electromagnetic type stylus acts as a signal emitter and the second sensing layer 210 act as a receiver. When the electromagnetic type stylus approaches the second sensing layer 210 to induce the magnetic flux change for generating the second sensing signal, the second touch module 216 calculates the second coordinate values based on the second sensing signal to find the position of the inductive operation. The switch unit 218 switches the first touch module 214 and the second touch module 216 to select either the first coordinate value or the second coordinate vale. The switch unit 218 may be universal serial bus (USB) hub.

In the present invention, an area of the processing circuit layer 212 is either greater than or equal to an area of the second sensing layer 210, and at least one metal area 230 is further formed on a spare area of the processing circuit layer 212 except for the area of the first touch module 214, the second touch module 216 and the switch unit 218. Specifically, the first touch module 214, the second touch module 216 and the switch unit 218 disposed on a predetermined area of the processing circuit layer 212 are distant from the circuits including the timing controller 222, a backlight driving module 224, and a power module 228 which easily make noise interference. In this manner, the calculation errors of the first sensing signal, the second sensing signal, the first coordinate value and the second coordinate value of the first touch module 214 and the second touch module 216 are avoided so that the first sensing signal and the second sensing signal has improved signal-to-noise ratio (SNR). That is, a plurality of circuit components, including the first touch module 214, the second touch module 216 and the switch unit 218, are integrated into the composite component layer 208 with the bigger area to properly arrange the positions of the circuit components for separating the circuit components from the elements, including the timing controller 222, a backlight driving module 224 and a power module 228, which easily make noise interference. Further, at least one metal area 230, e.g. copper material, is further formed on a spare area of the processing circuit layer 212 to decrease the electromagnetic interference (EMI) to meet the requirement of electromagnetic compatibility (EMC). That is, the processing circuit layer 212 utilizes the additional metal area 230 to improve the electromagnetic shielding for increasing the calculation accuracy of the first sensing signal, the second sensing signal, the first coordinate value and the second coordinate value.

In the processing circuit layer 212, the interface module 220 transmits a displaying output signal and either the selected first coordinate value or the selected second coordinate value. The interface module 220 is compatible to low voltage differential signaling (LVDS), a reduced swing differential signaling (RSDS) and the transistor-transistor logic (TTL). The displaying output signal, the first coordinate value and the selected second coordinate value are compatible to the signal format of the LVDS signal, the RSDS signal and the TTL signal. The timing controller 222 generates a timing controlling signal and a data signal based on the displaying output signal and either the selected first coordinate value or the selected second coordinate value. The backlight driving module 224 drives the backlight plate 206 according to the timing controlling signal. The driving circuit 226 drives the displaying layer 204 based on the timing controlling signal and the data signal. The power module 228 provides the integrated touch panel structure 200 with power for operation. The power module 228 utilizes batteries or the external power as the power source.

In the processing circuit layer 212, the first touch module 214, the second touch module 216 and the switch unit 218 are distant from the timing controller 222, the backlight driving module 224 and the power module 228 respectively at a predetermined distance, as shown in FIG. 1. The first touch module 214, the second touch module 216 and the switch unit 218 has the minimum noise interference from the timing controller 222, the backlight driving module 224 and the power module 228 within the predetermined distance. Additionally, when the circuit components including the first touch module 214, the second touch module 216 and the switch unit 218 are integrated into the composite component layer 208 with the bigger area, the transmission lines among the first touch module 214, the second touch module 216 and the switch unit 218 are shrunk and the widths of the transmission lines on the composite component layer 208 with the bigger area so that the resistance among the first touch module 214, the second touch module 216 and the switch unit 218 are also reduced. Moreover, when the circuit components including the first touch module 214, the second touch module 216 and the switch unit 218 are integrated into the composite component layer 208 with the bigger area, the heat dissipation area of the circuit components can be easily enlarged. Further, if the composite component layer 208 has the integrated second sensing layer 210, the circuit layout layer 211 and the processing circuit layer 212, the mechanical assembly strength of the integrated touch panel structure is enhanced to improve the assembly convenience.

In the composite component layer 208, the circuit layout layer 211, including Gamma circuit, ground circuit and control circuit, is positioned between the second sensing layer 210 and the processing circuit layer 212.

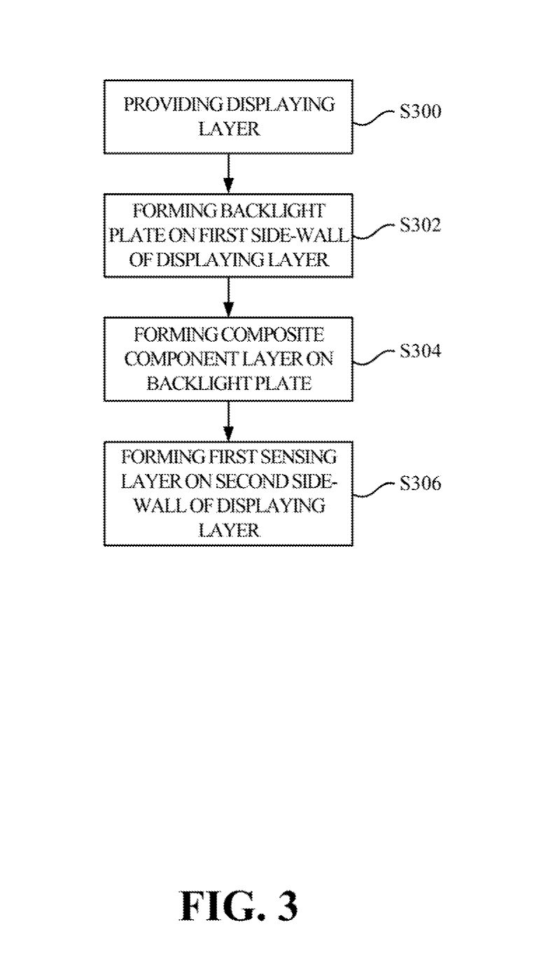

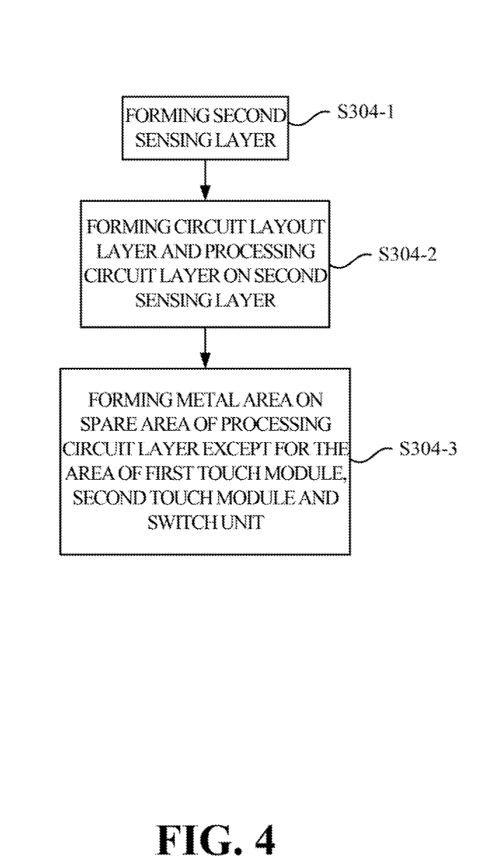

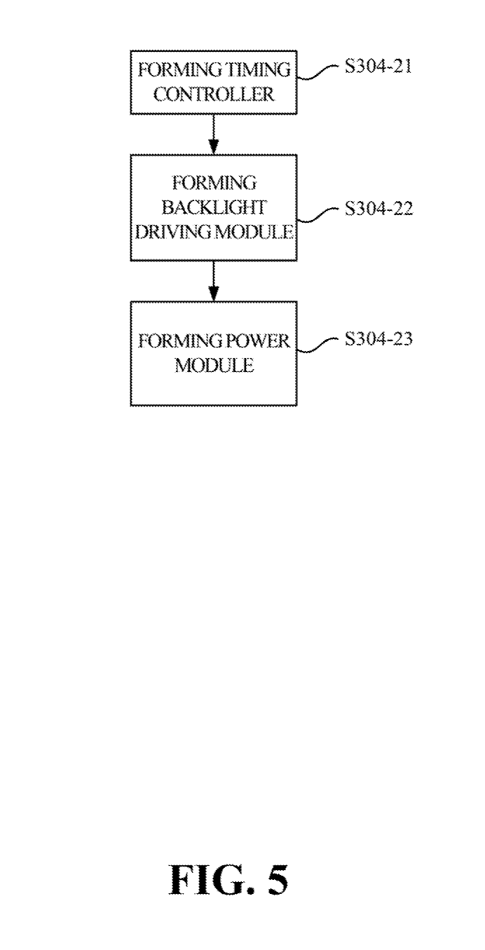

Please refer to FIGS. 1-5. FIG. 3 is a flow chart of a manufacturing method of the integrated touch panel structure 200 according to one embodiment of the present invention. FIG. 4 is a flow chart of forming a composite component layer 208 according to one embodiment of the present invention. The method of manufacturing an integrated touch panel structure includes the following steps.

In step S300, a displaying layer 204 is provided for displaying a program execution window thereon.

In step S302, a backlight plate 206 is formed on a first side-wall of the displaying layer 204.

In step S304, a composite component layer 208 is formed on the backlight plate 206 for electrically connecting the composite component layer 208 to the backlight plate 206, wherein the composite component layer 208 is opposite to the displaying layer 204 based on the backlight plate 206. The composite component layer 208 is a multi-layer printed circuit board. During the step S304 of forming the composite of component layer 208, it further includes the following steps. In step S304-1, a second sensing layer 210 is formed for contacting the backlight plate 206 and generating a second sensing signal by the second sensing layer 210. In one embodiment, the second sensing layer 210 is an electromagnetic type touch board. In step S304-2, a circuit layout layer 211 and the processing circuit layer 212 are formed on the second sensing layer 210 wherein the processing circuit layer 212 has a first touch module 214, a second touch module 216 and a switch unit 218, and an area of the processing circuit layer 212 is either greater than or equal to an area of the second sensing layer 210. In step S304-3, at least one metal area 230 is formed on a spare area of the processing circuit layer 212 except for the area of the first touch module 214, the second touch module 216 and the switch unit 218. That is, the processing circuit layer 212 has a metal area 230 except for the area of the first touch module 214, the second touch module 216 and the switch unit 218. Further, during the step S304-2 of forming the processing circuit layer on the second sensing layer, it further includes the following steps. In step S304-21, a timing controller 222 is formed for generating a timing controlling signal and a data signal. In step S304-22, a backlight driving module 224 is formed for driving the backlight plate 206 according to the timing controlling signal. In step S304-23, a power module 228 is formed for providing the integrated touch panel structure 200 with power for operation, wherein the first touch module 214, the second touch module 216 and the switch unit 218 are distant from the timing controller 222, the backlight driving module 224 and the power module 228 respectively at a predetermined distance (PD).

In step S306, a first sensing layer 202 is formed on a second side-wall of the displaying layer 204 opposite to the first side-wall to generate the first sensing signal by the first sensing layer 202. The first sensing layer 202 is a capacitive type touch board and electrically connected to the composite component layer 208.

In one embodiment, an area of the composite component layer 208 is either greater than or equal to an area of the first sensing layer 202. An area of the processing circuit layer 212 of the composite component layer 208 is either greater than or equal to an area of the second sensing layer 210. The manufacturing method of the integrated touch panel structure 200 in the present invention by integrating a plurality of circuit components into the composite component layer 208 with the bigger area to properly arrange the positions of the circuit components for separating the circuit components from the elements with noise interference. Further, the processing circuit layer 212 of the composite component layer 208 utilizes the additional metal area 230 to improve the electromagnetic shielding for increasing the calculation accuracy of the first sensing signal, the second sensing signal, the first coordinate value and the second coordinate value.

According to the above-mentioned descriptions, the present invention provides an integrated touch panel structure and manufacturing method thereof by integrating a plurality of circuit components into a composite component layer with bigger area to properly arrange the positions of the circuit components for effectively separating the circuit components from the elements with noise interference. Further, the spare area of the composite component layer is employed as the electromagnetic shielding area to reduce the electromagnetic interference of the sensing signals for increasing the calculation accuracy of the sensing signals. Additionally, the composite component layer is employed to shrink the transmission lines among the circuit components for reducing the resistance of the transmission lines. Moreover, the composite component layer is employed for enlarging the heat dissipation area of the circuit components and for improving the mechanical assembly strength of the integrated touch panel structure.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. An integrated touch panel structure, comprising:
a first sensing layer, generating a first sensing signal;
a displaying layer, displaying a program execution window wherein the first sensing layer is disposed on a first side-wall of the displaying layer;
a backlight plate disposed on a second side-wall opposite to the first side-wall of the displaying layer for generating a backlight to illuminate the displaying layer; and
a composite component layer disposed on the backlight plate and opposite to the displaying layer, the composite component layer comprising:
a second sensing layer, contacting the backlight plate and generating a second sensing signal; and
a processing circuit layer formed on the second sensing layer and having a first touch module corresponding to the first sensing layer, a second touch module corresponding to the second sensing layer and a switch unit, wherein an area of the processing circuit layer is either greater than or equal to an area of the second sensing layer, and at least one metal area is further formed on a spare area of the processing circuit layer except for the area of the first touch module, the second touch module and the switch unit.

2. The integrated touch panel structure of claim 1, wherein the first sensing layer is a capacitive type touch board.

3. The integrated touch panel structure of claim 1, wherein the first sensing layer is an electromagnetic type touch board.

4. The integrated touch panel structure of claim 1, wherein the composite component layer is a multi-layer printed circuit board.

5. The integrated touch panel structure of claim 1, wherein the first touch module converts the first sensing signal into a first coordinate value corresponding to a touch operation, the second touch module converts the second sensing signal into a second coordinate value corresponding to an inductive operation, and the switch unit switches the first touch module and the second touch module for selecting either the first coordinate value or the first coordinate value.

6. The integrated touch panel structure of claim 5, wherein the processing circuit layer further comprises:
an interface module coupled to the switch unit, transmitting a displaying output signal and either the selected first coordinate value or the selected second coordinate value;
a timing controller coupled to the interface module, generating a timing controlling signal and a data signal based on the displaying output signal and either the selected first coordinate value or the selected second coordinate value;
a backlight driving module coupled to the timing controller and the backlight plate, driving the backlight plate according to the timing controlling signal;
a driving circuit coupled to the timing controller, driving the displaying layer based on the timing controlling signal and the data signal; and
a power module, providing the integrated touch panel structure with power for operation;
wherein the first touch module, the second touch module and the switch unit are distant from the timing controller, the backlight driving module and the power module respectively at a predetermined distance.

7. The integrated touch panel structure of claim 1, wherein an area of the composite component layer is either greater than or equal to an area of the first sensing layer.

8. The integrated touch panel structure of claim 1, wherein the second sensing layer further comprises:
a first axial layer, sensing a directional signal of the second sensing signal along an coordinate X; and
a second axial layer disposed on the first axial layer and interlaced with the first axial layer wherein the second axial layer senses a directional of the second sensing signal along an coordinate Y perpendicular to the coordinate X.

9. The integrated touch panel structure of claim 1, wherein the first sensing layer generates the first sensing signal corresponding to a touch operation when the touch operation is performed on the program execution window, and the second sensing layer generates the second sensing signal corresponding to an inductive operation when the inductive operation is performed on the program execution window.

10. A method of manufacturing an integrated touch panel structure, the method comprising the steps of:
providing a displaying layer for displaying a program execution window thereon;
forming a backlight plate on a first side-wall of the displaying layer;
forming a composite component layer on the backlight plate for electrically connecting the composite component layer to the backlight plate, wherein the composite component layer is opposite to the displaying layer based on the backlight plate; and
forming a first sensing layer on a second side-wall of the displaying layer opposite to the first side-wall to generate the first sensing signal by the first sensing layer.

11. The method of claim 10, during the step of forming the composite of component layer, further comprising the steps of:
forming a second sensing layer for contacting the backlight plate and generating a second sensing signal by the second sensing layer;
forming a processing circuit layer on the second sensing layer wherein the processing circuit layer has a first touch module, a second touch module and a switch unit, and an area of the processing circuit layer is either greater than or equal to an area of the second sensing layer; and
forming at least one metal area on a spare area of the processing circuit layer except for the area of the first touch module, the second touch module and the switch unit.

12. The method of claim 11, during the step of forming the processing circuit layer on the second sensing layer, further comprising the steps of:
forming a timing controller for generating a timing controlling signal and a data signal;
forming a backlight driving module for driving the backlight plate according to the timing controlling signal; and
forming a power module for providing the integrated touch panel structure with power for operation;
wherein the first touch module, the second touch module and the switch unit are distant from the timing controller, the backlight driving module and the power module respectively at a predetermined distance.

13. The method of claim 11, wherein the first sensing layer generates the first sensing signal corresponding to a touch operation when the touch operation is performed on the program execution window, and the second sensing layer generates the second sensing signal corresponding to an inductive operation when the inductive operation is performed on the program execution window.

14. The method of claim 10, wherein the first sensing layer is a capacitive type touch board.

15. The method of claim 10, wherein the second sensing layer is an electromagnetic type touch board.

16. The method of claim 10, wherein the composite component layer is a multi-layer printed circuit board.

17. The method of claim 10, wherein an area of the composite component layer is either greater than or equal to an area of the first sensing layer.
